(19) United States
(12) Patent Application Publication
(10) Pub. No.: US 2002/0149912 A1
(43) Pub. Date: Oct. 17, 2002

(54) Heat sink dissipating heat by transformations of states of fluid

(76) Inventor: Shao-Kang Chu, Taipei Hsien (TW)

Correspondence Address: Michael D. Bednarek, SHAWPITTMAN, 1650 Tysons Boulevard, McLean, VA, 22102-4859, US

(21) Appl. No.: 09/988,303

(22) Filed: Nov. 19, 2001

(30) Foreign Application Priority Data
Apr. 17, 2001 (TW) 090109221

(51) Int. Cl. H05K 7/20

(52) U.S. Cl. 361/700

(57) ABSTRACT

A heat sink comprises a hollow body and a working fluid contained inside the hollow body. The hollow body is made of a heat-conductive material and further has a heat absorption end and a heat dissipation end. The heat absorption end has a bottom for contacting with a heat-generating element. The heat dissipation end has a plurality of protrusions for increasing surface exposed to surrounding air. The working fluid at the heat absorption end absorbs heat generated by the heat-generating element to be transformed from a liquid state to a gas state. Then, the working fluid in the gas state rises to the protrusions of the heat dissipation end for dissipating the heat to the surrounding air. The working fluid is transformed from the gas state to the liquid state to flow down back to the heat absorption end.

### REFERENCE TO RELATED APPLICATION

The present application claims priority to Taiwan application No.090109221, entitled “Heat Sink Dissipating Heat by Transformations of States of Fluid,” filed on Apr. 17, 2001.

### BACKGROUND OF THE INVENTION

(1) Field of the Invention

The invention relates to a heat sink, and more particularly to a heat sink which utilizes the transformations of states of the fluid to dissipate heat.

(2) Description of the Prior Art

Recently, electronic products in the market are rapidly updated and developed as the progress of the technology. An evidence to such a development is the truth that the large-scaled IC's or the VLSI's for electronic products become more and more complicated. For enhancing function of the product, it is one of good ways to design a new large-scaled IC's with more transistors in a unit area and a higher operation frequency. However, such a high-operation-frequency IC implies definitely that more heat will be generated. Therefore, it is obvious that how to dissipate the generated heat is a crucial topic for stabilizing the IC and extending its lifetime.

In prior art, the heat dissipation can be achieved by connecting a metal heat sink onto the element that generates the heat. The heat generated by the element can be transmitted from the element to the metal heat sink through the heat conductivity of the metal heat sink. Then, the metal heat sink dissipates the heat to the air through the surface of the heat sink that is exposed to the air. Obviously, the greater surface of the metal heat sink is exposed to the air, the more heat can be dissipated. In the case that the heat generated by the element is increased, the metal heat sink needs to enlarge its volume respectively for increasing heat-dissipation efficiency of the metal heat sink. However, due to heat-dissipation characteristics of the metal itself, it is found that the heat-dissipation efficiency of the metal heat sink is not increased in an equal proportion to the enlargement of its volume. Therefore, while using a high-operation frequency IC, volume and weight of the metal heat sink required for heat-dissipation will cause a substantial problem to the system that has the IC.

### SUMMARY OF THE INVENTION

Accordingly, it is a primary object of the present invention to provide a small-volume heat sink which has a high heat-dissipation efficiency.

The heat sink in accordance with the present invention is applied to an electronic system that includes a heat-generating element. The heat sink includes a hollow body and a working fluid contained in the hollow body. The hollow body, made of a heat-conductive material, further includes a heat absorption end and a heat dissipation end. The heat absorption end provides a bottom to connect with the heat-generating element. The heat dissipation end includes a plurality of protrusions that are provided to increase the surface exposed to surrounding air. In addition, the working fluid at the heat absorption end can absorb the heat transmitted from the heat-generating element so that the working fluid is transformed from a liquid state to a gas state. The working fluid in the gas state will rise upward to the protrusions of the heat dissipation end, and then at the dissipation end the working fluid will be transformed from the gas state to the liquid state by dissipating the heat to the surrounding air. The working fluid in the liquid state will flow back to the heat absorption end. Furthermore, the heat absorption end and the heat dissipation end can communicate with each other through a passage in between. By providing the passage, the configuration of the heat sink can then be adequately adjusted to meet the working space.

It is an advantage of the present invention that by utilizing the transformations of states of fluid to dissipate heat, the heat sink with a small volume has a high heat-dissipation efficiency, and has a good adjustability in shape to meet the application environment.

These and other objectives of the present invention will no doubt become obvious to those of ordinary skill in the art after having read the following detailed description of the preferred embodiment, which is illustrated in the various figures and drawings.

### BRIEF DESCRIPTION OF THE DRAWINGS

The present invention will now be specified with reference to its preferred embodiment illustrated in the drawings, in which

FIG. 1 is a cross sectional view of a preferred embodiment of the heat sink in accordance with the present invention; and

FIG. 2 is a cross sectional view of the heat sink of FIG. 1 applied to a notebook computer.

### DESCRIPTION OF THE PREFERRED EMBODIMENT

The invention disclosed herein is directed to a heat sink for dissipating heat by utilizing the transformations of states of the fluid. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

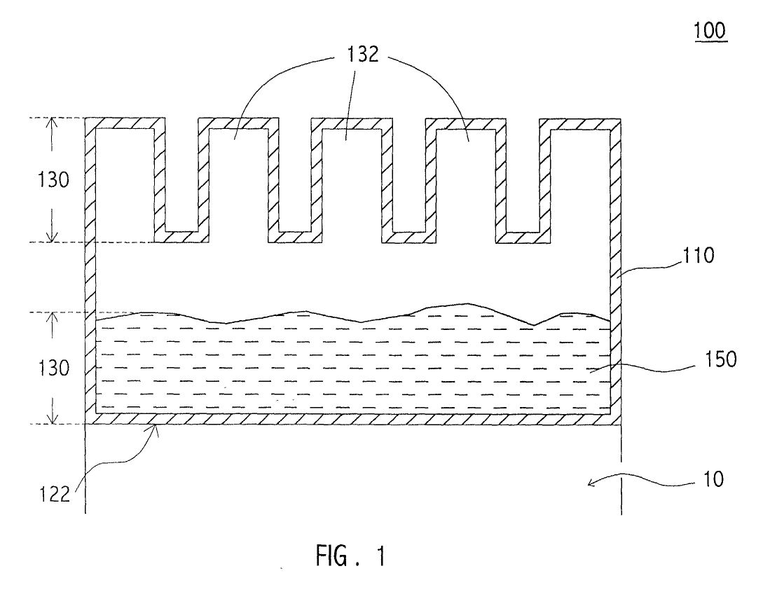

The heat sink in accordance with the present invention can be mounted in an electronic system such as a desktop computer or a notebook computer. Referring now to FIG. 1, a preferred embodiment of the heat sink according to the present invention is shown cross-sectionally. As shown, the heat sink 100 of the present invention can include a hollow body 110 and a working fluid 150. The heat sink 100 is an embodiment to be used in a desktop computer. The working fluid 150 is contained inside the hollow body 110. The material suitable to manufacture the hollow body 110 needs to have a good heat-conductivity; for example, a metal material. The hollow body 110 provides a heat absorption end 120 to contact with a heat-generating element 10. Opposing to the heat absorption end 120, a heat dissipation end 130 of the hollow body 110 locates higher than the heat absorption end 120 as shown. The heat absorption end 120 further includes a bottom 122 for directly connecting with the heat-generating element 10. A portion of the heat dissipation end 130 is formed as a plurality of protrusions 132. By providing such protrusions 132, contact area of the heat sink 100 with the surrounding air can be increased to enhance the heat dissipation efficiency of the heat sink 100. The working fluid 150 in a liquid state is located right above the bottom 122 of the heat absorption end 120. In the present invention, the working fluid 150 can be one of volatile fluids.

The heat produced by the heat-generating element 10 is transmitted to the working fluid 150 in the hollow body 110 through the bottom 122 of the heat absorption end 120. By absorbing the heat, the working fluid 150 is transformed from the liquid state to a gas state. The working fluid 150 in the gas state can rise up to the protrusions 132 of the heat dissipation end 130. At the protrusions 132, the heat in the working fluid 150 can be dissipated to the surrounding air. The working fluid can condense back to the liquid state after dissipating the heat to the air. Due to the gravity, the working fluid 150 in the liquid state can flow down back to the heat absorption end 120. Again, the working fluid 150 can absorb the heat produced by the heat-generating element 10 and be transformed to the gas state that will rise to the heat dissipation end 130. By providing aforesaid reciprocal state transformation upon the working fluid 150 inside the hollow body 110 of the heat sink 100, the heat generated by the heat-generating element 10 can be successfully dissipated by the heat sink 100 of the present invention.

One of many advantages of the heat sink 100 according to the present invention is that the configuration of the heat sink 100 can be adequately adjusted to satisfy particularly the environment requirement. For example, the notebook computer is usually light-weight and slim so that elements for the notebook computer are generally limited in shape and in volume. Therefore, the flexibility in shape provided by the heat sink 100 of the present invention can be much more welcome over prior art metal heat sink.

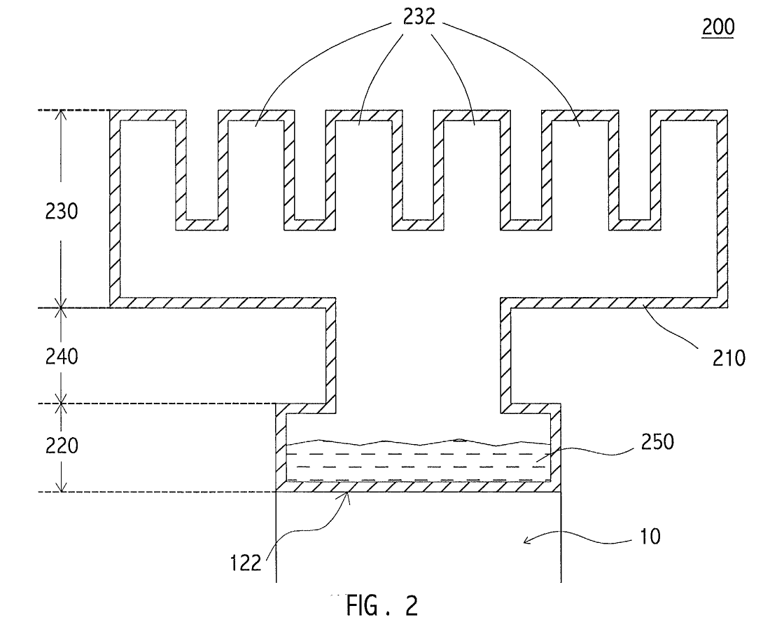

Referring now to FIG. 2, an application of the heat sink to a notebook computer is shown cross-sectionally. As shown, the heat sink 200 of the present invention can include a hollow body 210 and a working fluid 250. The working fluid 250 is contained inside the hollow body 210. The material suitable for manufacturing the hollow body 210 needs to have a good heat-conductivity; for example, a metal material. The hollow body 210 provides a heat absorption end 220 to contact with a heat-generating element 10. Opposing to the heat absorption end 220, a heat dissipation end 230 of the hollow body 210 is provided and can communicate with the heat absorption end 220 through a passage 240 in between as shown. The heat absorption end 220 further includes a bottom 222 for directly contracting with the heat-generating element 10. A portion of the heat dissipation end 230 is formed as a plurality of protrusions 232. By providing such protrusions 232, contact area of the heat sink 200 with the surrounding air can be increased so as to enhance the heat dissipation efficiency of the heat sink 200. The working fluid 150 in a liquid state is located right above the bottom 222 of the heat absorption end 220. In the present invention, the working fluid 250 can be one of volatile fluids.

In this embodiment, the heat sink 200 applies the same methodology as the previous heat sink 100 to achieve the heat-dissipation effect. The working fluid 250 can absorb the heat generated by the heat-generating element 10 to be transformed from the liquid state to a gas state. The working fluid 250 in the gas state can rise to the protrusions 232 through the passage 240. Then, by dissipating the heat to the surrounding air, the working fluid 250 can be transformed from the gas state to the liquid state so as to flow down back to the heat absorption end 220.

The major difference between the heat sink 200 of this embodiment and the heat sink 100 of the previous embodiment is the present of the passage 240. By providing the passage 240 to the heat sink 200, the working fluid 250 can freely commute between the heat absorption end 220 and the heat dissipation end 230. Furthermore, in this embodiment, because the heat-dissipation efficiency of the heat sink 200 depends mainly upon the vaporization rate and the condensation rate of the working fluid 250, so the heat-dissipation efficiency will not decrease even though the area of the cross section of the passage 240 is reduced. Therefore, while applying the present invention to the notebook computer, the passage 240 of the heat sink 200 can be made smaller and the heat dissipation end 230 can be made bigger, so that most space can be used for carrying out the heat dissipation not for the transmission of the working fluid 250. In addition, the design of the passage 240 can make the utilization of the interior space in the notebook computer more flexible.

Contrarily, the prior art metal heat sink utilizes the solid metal to absorb, transmit and dissipate the heat. Therefore, the heat-dissipation efficiency of the metal heat sink will decrease if the area of the cross section of the metal heat sink is reduced. Obviously, the adjustability in shape and in volume provided by the present invention is superior to that provided by the prior art metal heat sink.

By providing the heat sink in accordance with the present invention, following advantages are apparent:

1. Higher heat-dissipation efficiency with less space occupation; and

2. Better adjustability in shape to meet the application environment.

While the present invention has been particularly shown and described with reference to a preferred embodiment, it will be understood by those skilled in the art that various changes in form and detail may be without departing from the spirit and scope of the present invention.

What is claimed is:

1. A heat sink, applied to an electronic system having a heat-generating element, comprising:
a hollow body, made of a heat-conductive material, comprising:
a heat absorption end, having a bottom thereof for contacting with the heat-generating element; and
a heat dissipation end, having thereof a plurality of protrusions for increasing surface exposed to surrounding air; and
a working fluid, contained inside the hollow body;
wherein the working fluid at the heat absorption end absorbs heat generated by the heat-generating element to be transformed from a liquid state to a gas state, the working fluid in the gas state then rises to the protrusions of the heat dissipation end for dissipating the heat to the surrounding air, thereby the working fluid is transformed from the gas state to the liquid state to flow downward to the heat absorption end.

2. The heat sink according to claim 1, wherein said material is a metal.

3. The heat sink according to claim 1, wherein said working fluid is a volatile fluid.

4. The heat sink according to claim 1, wherein said electronic system is a desktop computer.

5. A heat sink, applied to an electronic system having a heat-generating element, comprising:
a hollow body, made of a heat-conductive material, comprising:
a heat absorption end, having a bottom thereof for contacting with the heat-generating element;
a heat dissipation end, having thereof a plurality of protrusions for increasing surface exposed to surrounding air; and
a passage for communicating the heat absorption end with the heat dissipation end; and
a working fluid, contained inside the hollow body;
wherein the working fluid at the heat absorption end absorbs heat generated by the heat-generating element to be transformed from a liquid state to a gas state, the working fluid in the gas state then rises to the protrusions of the heat dissipation end through the passage for dissipating the heat to the surrounding air, thereby the working fluid is transformed from the gas state to the liquid state to flow downward to the heat absorption end.

6. The heat sink according to claim 5, wherein said material is a metal.

7. The heat sink according to claim 5, wherein said working fluid is a volatile fluid.

8. The heat sink according to claim 5, wherein said electronic system is a notebook computer.
